(19) United States
(12) Patent Application Publication
(10) Pub. No.: US 2015/0069425 A1
(43) Pub. Date: Mar. 12, 2015

(54) LIGHT-EMITTING DEVICE MODULE AND METHOD OF MANUFACTURING SAME

(71) Applicant: SAMSUNG DISPLAY CO., LTD., YONGIN-CITY (KR)

(72) Inventors: Dong-Hwan Kim, Gyeonggi-Do (KR); Yong-Hoon Kwon, Gyeonggi-Do (KR); Hyuk-Hwan Kim, Gyeonggi-Do (KR); Seok-Hyun Nam, Gyeonggi-Do (KR)

(73) Assignee: SAMSUNG DISPLAY CO., LTD., YONGIN-CITY (KR)

(21) Appl. No.: 14/188,747

(22) Filed: Feb. 25, 2014

(30) Foreign Application Priority Data
Sep. 9, 2013 (KR) 10-2013-0108063

(51) Int. Cl. H01L 33/40; H01L 27/15; H01L 33/52

(52) U.S. Cl. CPC H01L 33/40; H01L 33/52; H01L 27/153
USPC 257/88; 257/99; 438/28

(57) ABSTRACT

A light-emitting device module includes a substrate and a light-emitting device disposed on the substrate. The light-emitting device may have a first pad and a second pad disposed thereon. A coating layer may cover the light-emitting device. The coating layer has a first via hole and a second via hole configured to respectively expose the first pad and the second pad therethrough. Wirings configured to be electrically connected to the first pad and the second pad through the first via hole and the second via hole are disposed on the coating layer.

### CROSS-REFERENCE TO RELATED APPLICATION

This application claims priority under 35 U.S.C. §119 to Korean Patent Application No. 10-2013-0108063, filed on Sep. 9, 2013, in the Korean Intellectual Property Office, the disclosure of which is incorporated by reference herein in its entirety.

### 1. TECHNICAL FIELD

Exemplary embodiments of the present invention relate to a light-emitting device module, and more particularly to a method of manufacturing the same.

### 2. DISCUSSION OF RELATED ART

Light-emitting devices have been used as, for example, a light source for a backlight unit in display devices. Light-emitting devices may be packaged in various forms before being assembled with a backlight module. The backlight unit may include a packaged light-emitting device package.

For example, the light-emitting device may be mounted on a lead frame including first and second leads. The first and second leads may be individually connected to the light-emitting device by wires and packaged. The light-emitting device package may be used as a light source for a backlight unit or the like.

### SUMMARY

To manufacture a light-emitting device package, a process of individually connecting the first and second leads to the light-emitting device by wires may be used. When the lead frame including the first and second leads is prepared, a large amount of copper may be used to form the lead frame including the first and second leads. The lead frame may be formed by forming a copper layer on an entire surface of a substrate and removing a portion of the copper layer through patterning of the copper layer.

One or more exemplary embodiments of the present invention include a light-emitting device module for realizing a high-resolution display with reduced manufacturing costs and a reduced size and a method of manufacturing the same. The exemplary embodiments of the present invention are only illustrative, and the scope of the present invention is not limited thereto.

Exemplary embodiments of the present invention will be set forth in the description which follows and additional aspects of the present invention, in part, will be apparent from the description, or may be learned by practice of the exemplary embodiments.

According to one or more exemplary embodiments of the present invention, a light-emitting device module includes a substrate and a light-emitting device disposed on the substrate. The light-emitting display device has a first pad and a second pad disposed thereon. A coating layer covers the light-emitting device. The coating layer has a first via hole and a second via hole configured to respectively expose the first pad and the second pad therethrough. Wirings are configured to be electrically connected to the first pad and the second pad through the first via hole and the second via hole. The wirings are disposed on the coating layer.

According to an exemplary embodiment of the present invention, the coating layer may cover the entire surface of the substrate.

According to an exemplary embodiment of the present invention, the light-emitting device module may include an adhesive. The adhesive may be configured to fix the light-emitting device onto the substrate.

According to an exemplary embodiment of the present invention, the wirings may include copper (Cu).

According to an exemplary embodiment of the present invention, each of the wiring may include a first wiring layer configured to be electrically connected to the first pad or the second pad through the first via hole or the second via hole. The first wiring layer may be disposed on the coating layer. A second wiring layer may be disposed on the first wiring layer.

According to an exemplary embodiment of the present invention, the first wiring layer may include silver (Ag), and the second wiring layer may include Cu. The second wiring layer need not be located in the first via hole and the second via hole.

According to an exemplary embodiment of the present invention, the substrate and the coating layer may include a same material. The substrate and the coating layer may be a single body.

According to an exemplary embodiment of the present invention, the coating layer may include a light-transmitting material.

According to an exemplary embodiment of the present invention, the coating layer may include polyimide.

According to one or more exemplary embodiments of the present invention, a light-emitting device module includes a plurality of light-emitting devices disposed on a substrate. Each of the light-emitting devices is separated from each other. Each of the light-emitting devices has a first pad and a second pad disposed thereon. The light-emitting device module includes a film wrapping the plurality of light-emitting devices. The film has first via holes and second via holes configured to respectively expose the first pads and the second pads of the plurality of light-emitting devices. Wirings are disposed on the film. The wirings are configured to be electrically connected to the first pads and the second pads through the first via holes and the second via holes.

According to one or more exemplary embodiments of the present invention, a method of manufacturing a light-emitting device module includes disposing a light-emitting device having a first pad and a second pad on a substrate. A coating layer is formed to cover the light-emitting device. A first via hole and a second via hole are formed in the coating layer to respectively expose the first pad and the second pad of the light-emitting device therethrough. Wirings are formed on the coating layer. The wirings are electrically connected to the first pad and the second pad of the light-emitting device.

According to an exemplary embodiment of the present invention, the forming of the coating layer may include forming the coating layer to cover the entire surface of the substrate.

According to an exemplary embodiment of the present invention, the disposing of the light-emitting device may include disposing the light-emitting device by fixing the light-emitting device onto the substrate with an adhesive.

According to an exemplary embodiment of the present invention, the forming of the wirings on the coating layer may include printing a copper (Cu) paste on the coating layer to contact the first pad and the second pad of the light-emitting device.

According to an exemplary embodiment of the present invention, the forming of the wirings on the coating layer may include forming a first wiring layer by printing a paste including a first conductive material on the coating layer to contact the first pad and the second pad of the light-emitting device. The forming of the wirings on the coating layer may include forming a second wiring layer on the first wiring layer by plating a second conductive material on the first wiring layer. The first conductive material may include silver (Ag), and the second conductive material may include Cu.

According to an exemplary embodiment of the present invention, the first conductive material may include silver (Ag), and the second conductive material may include copper (Cu).

According to an exemplary embodiment of the present invention, the forming of the coating layer may include forming the coating layer using a same material as the substrate.

According to an exemplary embodiment of the present invention, the coating layer may include a light-transmitting material.

According to an exemplary embodiment of the present invention, the coating layer may include polyimide.

### BRIEF DESCRIPTION OF THE DRAWINGS

The above and other features of the present invention will become more apparent by describing in detail exemplary embodiments thereof, with reference to the accompanying drawings in which:

FIGS. 1 to 4 are schematic cross-sectional views illustrating a method of manufacturing a light-emitting device module according to an exemplary embodiment of the present invention;

FIG. 5 is a schematic cross-sectional view of a light-emitting device module manufactured by a method according to an exemplary embodiment of the present invention; and

FIG. 6 is a schematic perspective view of a light-emitting device module according to an exemplary embodiment of the present invention.

### DETAILED DESCRIPTION

Hereinafter, exemplary embodiments of the present invention will be described in detail with reference to the accompanying drawings. However, the present invention should not be construed as limited to the exemplary embodiments set forth herein and may be embodied in different forms. Like reference numerals may refer to the like elements.

It will be understood that when a layer, region, or component is referred to as being “formed on,” another layer, region, or component, it may be directly or indirectly formed on the other layer, region, or component. For example, intervening layers, regions, or components may be present.

Sizes of elements in the drawings may be exaggerated for convenience of explanation. Sizes and thicknesses of components in the drawings may be arbitrarily illustrated for convenience of explanation and the following exemplary embodiments of the present invention are not limited thereto.

In the following examples, the x-axis, the y-axis and the z-axis may not be limited to three axes of the rectangular coordinate system, and may be interpreted in a broader sense. For example, the x-axis, the y-axis, and the z-axis may be perpendicular to one another, or may represent different directions that are not perpendicular to one another.

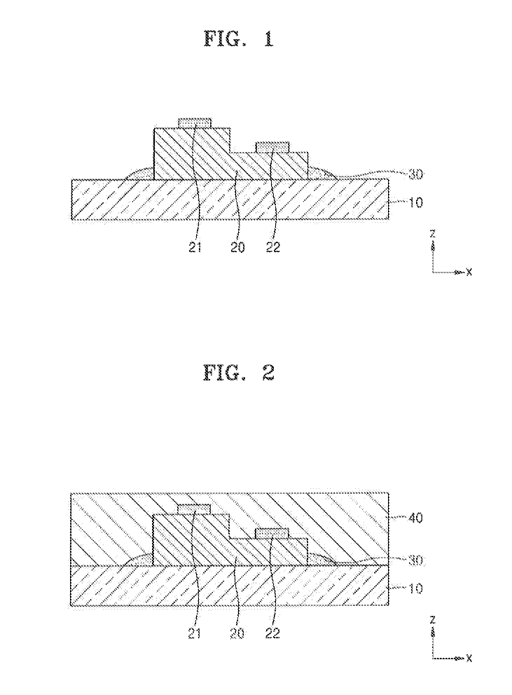

FIGS. 1 to 4 are schematic cross-sectional views illustrating a method of manufacturing a light-emitting device module according to an exemplary embodiment of the present invention.

According to the method of manufacturing a light-emitting device module according to an exemplary embodiment of the present invention, a light-emitting device 20 is disposed on a substrate 10 as shown in FIG. 1, for example. The light-emitting device 20 may be disposed on the substrate 10 by fixing the light-emitting device 20 onto the substrate 10 by an adhesive 30 as shown in FIG. 1, for example. The adhesive 30 may be interposed between the light-emitting device 20 and the substrate 10. As shown in FIG. 1, for example, the adhesive 30 may be disposed around the light-emitting device 20.

For example, the substrate 10 may include polyimide. For example, an FR4 substrate or a CEM-3 substrate used as a printed circuit board may be used. When a polyimide substrate is used as the substrate 10, a flexible light-emitting device module may be formed, for example.

The light-emitting device 20 may be a device for emitting light by receiving an electrical signal and may be used as a light source for various electronic devices. For example, the light-emitting device 20 may include a diode of a compound semiconductor. The light-emitting device 20 may be referred to as a light-emitting diode (LED). The LED may emit light of various wavelengths, for example, according to materials of the compound semiconductor. The light-emitting device 20 may have a first pad 21 and a second pad 22. The first pad 21 and/or the second pad 22 may receive an electrical signal.

After disposing the light-emitting device 20 on the substrate 10, a coating layer 40 may be formed. The coating layer 40 may cover the light-emitting device 20, as shown in FIG. 2, for example. The coating layer 40 may include a light-transmitting material, for example, polyimide, epoxy, or the like. The coating layer 40 may be formed by a spin coating method. For example, by using the spin coating method, the coating layer 40 covering the light-emitting device 20 and the entire surface of the substrate 10 may be formed.

As shown in FIG. 3, for example, a first via hole 40a and a second via hole 40b may be formed in the coating layer 40. The first via hole 40a and the second via hole 40b may respectively expose the first pad 21 and the second pad 22 of the light-emitting device 20 therethrough.

Various methods may be used to form the first via hole 40a and the second via hole 40b. For example, as shown in FIG. 3, the first via hole 40a and the second via hole 40b may be formed in the coating layer 40 to respectively expose the first pad 21 and the second pad 22 of the light-emitting device 20 therethrough by forming a photoresist layer on the coating layer 40, light-exposing and developing the photoresist layer to expose only a portion where the first via hole 40a and the second via hole 40b of the coating layer 40 are to be formed, forming the first via hole 40a and the second via hole 40b through etching or the like, and removing the remaining photoresist layer. Alternatively, the first via hole 40a and the second via hole 40b may be formed in the coating layer 40 to respectively expose the first pad 21 and the second pad 22 of the light-emitting device 20 therethrough by removing a portion of the coating layer 40 where the first via hole 40a and the second via hole 40b of the coating layer 40 are to be formed through irradiation of laser beams only on the portion of the coating layer 40 where the first via hole 40a and the second via hole 40b are to be formed.

When a laser etching method is used, the first via hole 40a and the second via hole 40b may be formed by the laser etching method so that a portion of the coating layer 40 is not damaged, except the first via hole 40a and the second via hole 40b of the coating layer 40. For example, when the coating layer 40 includes polyimide and when laser beams are irradiated thereon, only a portion of the coating layer 40 on which the laser beams are irradiated might be removed, and another portion of the coating layer 40 might not be removed.

After forming the first via hole 40a and the second via hole 40b in the coating layer 40, as shown in FIG. 4, for example, wirings 50 electrically connected to the first pad 21 and the second pad 22 of the light-emitting device 20 may be formed on the coating layer 40. FIG. 4 shows, for example, two wirings 50 wherein one wiring 50 is electrically connected to the first pad 21 and the other wiring 50 is electrically connected to the second pad 21. When at least a portion of the first pad 21 and the second pad 22 of the light-emitting device 20 is exposed due to the existence of the first via hole 40a and the second via hole 40b in the coating layer 40, the wirings 50 may contact the first pad 21 and the second pad 22 of the light-emitting device 20 through the first via hole 40a and the second via hole 40b when the wirings 50 are formed on the coating layer 40. The wirings 50 may be formed by printing a copper (Cu) paste on the coating layer 40 to contact the first pad 21 and the second pad 22 of the light-emitting device 20.

To manufacture the light-emitting device package of FIG. 4, for example, a process of preparing a lead frame including a first lead and a second lead and respectively connecting a first pad 21 and a second pad 22 of a light-emitting device to the first lead and the second lead by wires may be performed. To connect the first lead and the second lead to the light-emitting device by wires, the sizes of the first lead and the second lead may be relatively large, and the total size of the light-emitting device package may be large.

According to a method of manufacturing a light-emitting device module according to an exemplary embodiment of the present invention, the process of connecting the first lead and the second lead to the light-emitting device by wires may be skipped. When the wirings 50 are formed in the coating layer 40 by a printing method, for example, the wirings 50 contacting the first pad 21 and the second pad 22 of the light-emitting device 20 through the first via hole 40a and the second via hole 40b located on the first pad 21 and the second pad 22 may be formed. A space for wirings 50 required for a light-emitting device package may be manufactured according to a method of manufacturing a light-emitting device package according to an exemplary embodiment of the present invention and a total size of the light-emitting device module may be reduced.

For example, when a size of a light-emitting device package is relatively large and a display is formed using the light-emitting device package, a pixel size may be large, and a pitch between pixels may be accordingly large, and it may be difficult to implement a high-resolution display. When the size of the light-emitting device module manufactured by the method of manufacturing a light-emitting device module according to exemplary embodiments of the present invention is small, and a high-resolution display may be formed using the light-emitting device module.

According to a method of manufacturing a light-emitting device package according to an exemplary embodiment of the present invention, when the lead frame including the first lead and the second lead is prepared, the lead frame including the first lead and the second lead may be formed by forming a Cu layer on the entire surface of a substrate and patterning the Cu layer to remove a portion of the Cu layer. When an amount of Cu removed in a process of forming the lead frame is relatively large, manufacturing costs may be increased. According to the method of manufacturing a light-emitting device module according to an exemplary embodiment of the present invention, when the wirings 50 are formed by a printing method, for example, an amount of a material consumed to form the wirings 50 may be reduced.

When the coating layer 40 is formed, the coating layer 40 may include the same material as the substrate 10. For example, the substrate 10 may include polyimide. For example, the coating layer 40 may be formed by coating polyimide on the substrate 10 by spin coating. The substrate 10 and the coating layer 40 may be a single body. For example, the substrate 10 and the coating layer 40 may be formed integrally, and an interface might not exist therebetween. A light-emitting device module in a form of chip in film may be formed by the method of manufacturing a light-emitting device module according to an exemplary embodiment of the present invention.

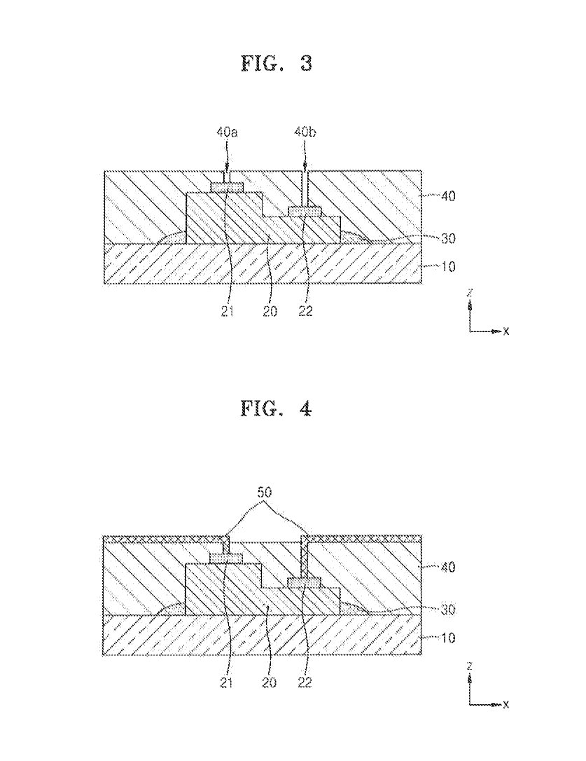

FIG. 5 is a schematic cross-sectional view of a light-emitting device module manufactured by a method of manufacturing a light-emitting device module according to an exemplary embodiment of the present invention. According to the method of manufacturing the light-emitting device module according to an exemplary embodiment of the present invention, as shown in FIG. 3, for example, a first wiring layer 51 may be formed by forming the first via hole 40a and the second via hole 40b in the coating layer 40 to respectively expose the first pad 21 and the second pad 22 of the light-emitting device 20 therethrough and printing a paste including a first conductive material on the coating layer 40 to contact the first pad 21 and the second pad 22 of the light-emitting device 20. A second wiring layer 52 may be formed by plating a second conductive material on the first wiring layer 51. The first conductive material may include, for example, silver (Ag), and the second conductive material may include, for example, Cu.

The wirings 50 may be formed by printing a Cu paste on the coating layer 40 to contact the first pad 21 and the second pad 22 of the light-emitting device 20. When a Cu paste is printed a defective rate may be high. When an Ag paste is formed, as shown in FIG. 5, for example, the first wiring layer 51 contacting the first pad 21 and the second pad 22 of the light-emitting device 20 may be formed by a printing method. When the second wiring layer 52 including Cu is formed only on the first wiring layer 51 including Ag by using a seed layer through plating or the like, the conductivity of the wirings 50 may be increased by the second wiring layer 52, and the waste of Cu may be reduced when the second wiring layer 52 is formed.

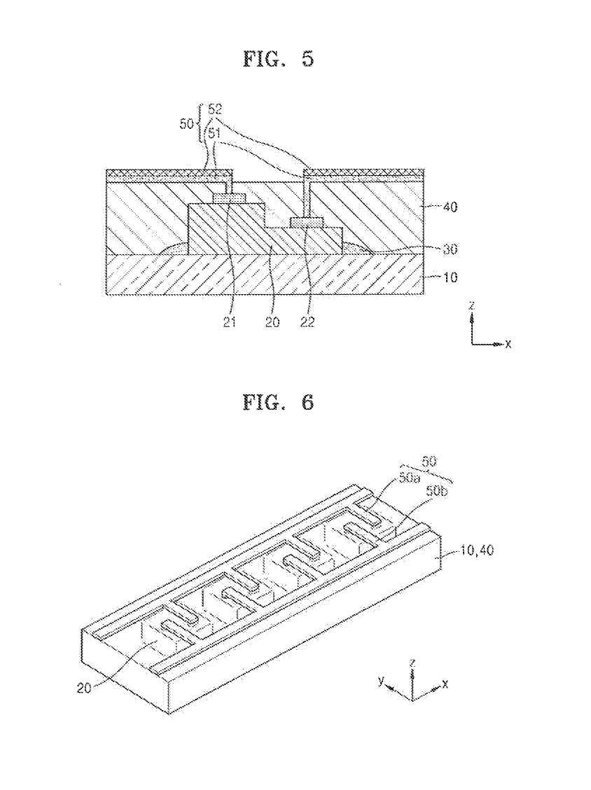

A light-emitting device module as shown in FIG. 6, for example, may be manufactured using a method of manufacturing a light-emitting device module according to an exemplary embodiment of the present invention. A plurality of light-emitting devices 20 may be disposed on the substrate 10. The coating layer 40 may cover the plurality of light-emitting devices 20. First via holes 40a and second via holes 40b may be formed and may respectively expose first pads 21 and second pads 22 of the plurality of light-emitting devices 20. The wirings 50 may be disposed on the coating layer 40. A wiring 50a may be commonly and electrically connected to each of the first pads 21 of the plurality of light-emitting devices 20. A wiring 50b may be commonly and electrically connected to each of the second pads of the plurality of light-emitting devices 20. A bar-shaped light-emitting device module having the plurality of light-emitting devices 20 may be formed. When separate wiring is not used, a distance (pitch) between the plurality of light-emitting devices 20 may be reduced, thereby implementing a bar-shaped light-emitting device module capable of emitting light of high brightness with a small size.

Although exemplary methods of manufacturing a light-emitting device module according to exemplary embodiments of the present invention have been described, the scope of the present invention is not limited thereto. For example, a light-emitting device module may belong to the scope of the present invention.

A light-emitting device module according to an exemplary embodiment of the present invention may have, for example, a shape as shown in FIG. 4. The light-emitting device module according to an exemplary embodiment of the present invention may include the substrate 10, the light-emitting device 20, the coating layer 40, and the wirings 50.

The substrate 10 may include, for example, polyimide. The light-emitting device 20 may be disposed on the substrate 10 and may have the first pad 21 and the second pad 22 disposed thereon. The light-emitting device 20 may be fixed to the substrate 10 by the adhesive 30 as shown in FIG. 1, for example. The coating layer 40 may cover the light-emitting device 20 and may include the first via hole 40a and the second via hole 40b. The first via hole 40a and the second via hole 40b may be configured to expose the first pad 21 and the second pad 22 therethrough. The coating layer 40 may include a light-transmitting material, for example, polyimide, epoxy, or the like. The coating layer 40 may cover the light-emitting device 20 and/or the entire surface of the substrate 10. The wirings 50 may be electrically connected to the first pad 21 and the second pad 22 through the first via hole 40a and the second via hole 40b. The wirings 50 may be disposed on the coating layer 40. The wirings 50 may include Cu.

The light-emitting device package may include a lead frame including a first lead and a second lead, and a first pad 21 and a second pad 22. The light-emitting device on the lead frame may be connected to the first lead and the second lead of the lead frame by wires. To connect the first lead and the second lead to the light-emitting device by wires, sizes of the first lead and the second lead may be relatively large, and a total size of the light-emitting device package may be relatively large.

The light-emitting device module according to an exemplary embodiment of the present invention may not include a connection using wires. For example, when the wirings 50 are formed by a printing method and are located on the coating layer 40, the wirings 50 may directly contact the first pad 21 and the second pad 22 of the light-emitting device 20 through the first via hole 40a and the second via hole 40b located on the first pad 21 and the second pad 22. When a space for wiring does not exist, a total size of the light-emitting device module may be reduced.

When the size of the light-emitting device package is large and a display is formed using the light-emitting device package, a pixel size may be large, and a pitch between pixels may be accordingly large and it may be difficult to implement a high-resolution display. When the size of the light-emitting device module according to an exemplary embodiment of the present invention is small, a high-resolution display may be formed using the light-emitting device module.

When the lead frame including the first lead and the second lead is prepared, the lead frame including the first lead and the second lead may be formed by forming a Cu layer on the entire surface of a substrate and patterning the Cu layer to remove a portion of the Cu layer. An amount of Cu removed in a process of forming the lead frame may be large, thereby increasing manufacturing costs. In the light-emitting device module according to an exemplary embodiment of the present invention, when the wirings 50 are formed by a printing method, for example, an amount of a material consumed to form the wirings 50 may be reduced. In the light-emitting device module according to an exemplary embodiment of the present invention, costs for manufacturing the light-emitting device module may be reduced.

The substrate 10 and the coating layer 40 may include a same material. For example, the substrate 10 may include a polyimide. The coating layer 40 may be formed by spin-coating a polyimide. The substrate 10 and the coating layer 40 may be a single body, and an interface might not exist therebetween. The light-emitting device module according to an exemplary embodiment of the present invention may be a chip in film light-emitting device module.

In a light-emitting device module according to an exemplary embodiment of the present invention, the wirings 50 may include the first wiring layer 51 and the second wiring layer 52 as shown in FIG. 5, for example. The first wiring layer 51 may be electrically connected to the first pad 21 and the second pad 22 through the first via hole 40a and the second via hole 40b. The first wiring layer 51 may be disposed on the coating layer 40. The second wiring layer 52 may be disposed on the first wiring layer 51. The first wiring layer 51 may be formed by printing a paste including the first conductive material on the coating layer 40 to contact the first pad 21 and the second pad 22 of the light-emitting device 20. The second wiring layer 52 may be formed by plating the second conductive material on the first wiring layer 51. The first conductive material may include, for example, Ag, and the second conductive material may include, for example, Cu.

The wirings 50 may be formed by printing a Cu paste on the coating layer 40 to contact the first pad 21 and the second pad 22 of the light-emitting device 20. The Cu paste may be difficult to form, and when the Cu paste is formed, a defect rate may be high. An Ag paste may be easier to manufacture and easier to print. For example, when the Ag paste is used, as shown in FIG. 5, the first wiring layer 51 contacting the first pad 21 and the second pad 22 of the light-emitting device 20 may be formed by a printing method. For example, when the second wiring layer 52 including Cu is formed on the first wiring layer 51 including Ag by using a seed layer through plating or the like, the conductivity of the wirings 50 may be increased by the second wiring layer 52. The waste of Cu may be reduced when the second wiring layer 52 is formed.

In the light-emitting device module according to an exemplary embodiment of the present invention, when the second wiring layer 52 may be formed using the first wiring layer 51 as a seed layer through a plating method, the second wiring layer 52 may not be disposed in the first via hole 40a and the second via hole 40b because the first wiring layer 51 is disposed in the first via hole 40a and the second via hole 40b.

FIG. 6 is a schematic perspective view of a light-emitting device module according to an exemplary embodiment of the present invention. As shown in FIG. 6, the light-emitting device module according to an exemplary embodiment of the present invention may have a structure in which a plurality of light-emitting devices 20 are disposed on the substrate 10. The coating layer 40 may cover the plurality of light-emitting devices 20. The coating layer 40 may have first via holes 40a and second via holes 40b. The first via holes 40a and second via holes 40b may respectively expose first pads 21 and second pads 22 of the plurality of light-emitting devices 20. The wirings 50 may be located on the coating layer 40. The wirings 50 may include a wiring 50a and a wiring 50b, wherein the wiring 50a is commonly and electrically connected to each of the first pads 21 of the plurality of light-emitting devices 20. The wiring 50b may be commonly and electrically connected to each of the second pads 22 of the plurality of light-emitting devices 20.

The light-emitting device module according to an exemplary embodiment of the present invention may include the plurality of light-emitting devices 20 separated from each other and having the first pads 21 and the second pads 22. The substrate 10 and/or the coating layer 40 may wrap the plurality of light-emitting devices 20 to be located therein. The substrate 10 and/or the coating layer 40 may have the first via holes 40a and the second via holes 40b formed therein. The first via holes 40a and the second via holes 40b may respectively expose first pads 21 and second pads 22 of the plurality of light-emitting devices 20 therethrough. The wirings 50 may be electrically connected to the first pads 21 and the second pads 22 through the first via holes 40a and the second via holes 40b. The wirings 50 may be disposed on the substrate 10 and/or the coating layer 40.

According to the exemplary embodiments described above, a bar-shaped light-emitting device module having the plurality of light-emitting devices 20 may be formed. For example, when separate wiring steps are not needed, a distance (pitch) between the plurality of light-emitting devices 20 may be reduced and a bar-shaped light-emitting device module capable of emitting light of high brightness with a small size may be formed.

As described above, according to one or more of the above exemplary embodiments of the present invention, a light-emitting device module for a high-resolution display with reduced manufacturing costs and a reduced size may be formed and a method of manufacturing the same may be performed. The scope of the present invention is not limited to effects thereof.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A light-emitting device module, comprising:
a substrate;
a light-emitting device disposed on the substrate, wherein the light-emitting device has a first pad and a second pad disposed thereon;
a coating layer covering the light-emitting device, wherein the coating layer has a first via hole and a second via hole configured to respectively expose the first pad and the second pad therethrough; and
wirings configured to be electrically connected to the first pad and the second pad through the first via hole and the second via hole, wherein the wirings are disposed on the coating layer.

2. The light-emitting device module of claim 1, wherein the coating layer covers the entire surface of the substrate.

3. The light-emitting device module of claim 1, further comprising an adhesive, wherein the adhesive is configured to fix the light-emitting device onto the substrate.

4. The light-emitting device module of claim 1, wherein the wirings include copper (Cu).

5. The light-emitting device module of claim 1, wherein the wirings comprise:
a first wiring layer configured to be electrically connected to the first pad or the second pad through the first via hole or the second via hole, wherein the first wiring layer is disposed on the coating layer; and
a second wiring layer disposed on the first wiring layer.

6. The light-emitting device module of claim 5, wherein the first wiring layer includes silver (Ag), and the second wiring layer includes copper (Cu).

7. The light-emitting device module of claim 1, wherein the substrate and the coating layer include a same material.

8. The light-emitting device module of claim 7, wherein the substrate and the coating layer are a single body.

9. The light-emitting device module of claim 1, wherein the coating layer includes a light-transmitting material.

10. The light-emitting device module of claim 1, wherein the coating layer includes polyimide.

11. A light-emitting device module, comprising:
a plurality of light-emitting devices separated from each other, wherein each light-emitting device has a first pad and a second pad disposed thereon;
a film wrapping the plurality of light-emitting devices, wherein the film has first via holes and second via holes configured to respectively expose the first pads and the second pads of the plurality of light-emitting devices; and
wirings disposed on the film, wherein the wirings are configured to be electrically connected to the first pads and the second pads through the first via holes and the second via holes.

12. A method of manufacturing a light-emitting device module, the method comprising;
disposing a light-emitting device having a first pad and a second pad on a substrate;
forming a coating layer over the light-emitting device;
forming a first via hole and a second via hole in the coating layer to respectively expose the first pad and the second pad of the light-emitting device therethrough; and
forming wirings on the coating layer, wherein the wirings are electrically connected to the first pad and the second pad of the light-emitting device.

13. The method of claim 12, wherein the forming of the coating layer comprises forming the coating layer to cover the entire surface of the substrate.

14. The method of claim 12, wherein the disposing of the light-emitting device comprises disposing the light-emitting device by fixing the light-emitting device onto the substrate with an adhesive.

15. The method of claim 12, wherein the forming of the wirings on the coating layer comprises printing a copper (Cu) paste on the coating layer to contact the first pad and the second pad of the light-emitting device.

16. The method of claim 12, wherein the forming of the wirings on the coating layer comprises:
forming a first wiring layer by printing a paste including a first conductive material on the coating layer to contact the first pad and the second pad of the light-emitting device; and
forming a second wiring layer on the first wiring layer by plating a second conductive material on the first wiring layer.

17. The method of claim 16, wherein the first conductive material includes silver (Ag), and the second conductive material includes copper (Cu).

18. The method of claim 12, wherein the forming of the coating layer comprises forming the coating layer using a same material as the substrate.

19. The method of claim 12, wherein the coating layer includes a light-transmitting material.

20. The method of claim 12, wherein the coating layer includes polyimide.
